(19) United States
(12) Patent Application Publication
(10) Pub. No.: US 2023/0351072 A1
(43) Pub. Date: Nov. 2, 2023

(54) SIMULATION SYSTEM, SIMULATION METHOD, AND RECORDING MEDIUM

(71) Applicant: Panasonic Intellectual Property Management Co., Ltd., Osaka (JP)

(72) Inventors: Shigeaki SAKURAZAWA, KANAGAWA KEN (JP); Daishi IWAMOTO, KANAGAWA KEN (JP)

(73) Assignee: Panasonic Intellectual Property Management Co., Ltd., Osaka (JP)

(21) Appl. No.: 18/220,095

(22) Filed: Jul. 10, 2023

Related U.S. Application Data
(63) Continuation of application No. PCT/JP2021/045215, filed on Dec. 8, 2021.

(30) Foreign Application Priority Data
Feb. 19, 2021 (JP) 2021-025604

(51) Int. Cl. G06F 30/20; H04B 17/391

(52) U.S. Cl. CPC G06F 30/20; H04B 17/3912

(57) ABSTRACT

A simulation system includes a driving simulator, a radio propagation simulator, and an application simulator. The driving simulator generates a driving scenario representing at least behavior of a vehicle. The radio propagation simulator calculates a propagation parameter representing a radio wave to be received by one or more antennas installed in the vehicle. The propagation parameter is calculated on the basis of antenna performance of the one or more antennas and a position of the vehicle. The position of the vehicle is indicated by the driving scenario generated by the driving simulator. The application simulator simulates operation of an application serving to control operation of the vehicle. The operation of the application is simulated by using at least information based on the propagation parameter.

### CROSS-REFERENCE TO RELATED APPLICATIONS

This application is a continuation of International Application No. PCT/JP2021/045215, filed on Dec. 8, 2021 which claims the benefit of priority of the prior Japanese Patent Application No. 2021-025604, filed on Feb. 19, 2021, the entire contents of which are incorporated herein by reference.

### FIELD

The present disclosure relates to a simulation system, a simulation method, and a recording medium.

### BACKGROUND

Demand for connected cars has increased, and the technology of Vehicle to X (V2X) for performing communication between a vehicle, a pedestrian, a roadside unit, and the like has been required. Tests for evaluating operations of an Intelligent Transport Systems (ITS) application using such V2X have been conducted by an integrated simulator. As a technology related to such an integrated simulator, for example, a technology of performing simulation while varying transmitted power from a vehicle based on a normal distribution has been disclosed (for example, a patent literature JP 2011-164983 A). Additionally, a technology of performing simulation while providing an index of a jamming degree based on a distance between communications has been disclosed (for example, a patent literature WO 2015/132863 A).

### SUMMARY

A simulation system according to the present disclosure includes a driving simulator, a radio propagation simulator, and an application simulator. The driving simulator is configured to generate a driving scenario representing at least behavior of a vehicle. The radio propagation simulator is configured to calculate a propagation parameter representing a radio wave to be received by one or more antennas installed in the vehicle. The propagation parameter is calculated on the basis of antenna performance of the one or more antennas and a position of the vehicle. The position of the vehicle is indicated by the driving scenario generated by the driving simulator. Then application simulator is configured to simulate operation of an application serving to control operation of the vehicle. The operation of the application is simulated by using at least information based on the propagation parameter.

### BRIEF DESCRIPTION OF THE DRAWINGS

FIG. 1 is a diagram illustrating an overall configuration example of an integrated simulation system according to an embodiment;

FIG. 2 is a diagram illustrating an example of operation of each component and a flow of data in an integrated simulation system according to the embodiment;

FIG. 3 is a diagram describing an example of simulation of operation of a vehicle that is based on a driving scenario in an integrated simulation system according to the embodiment;

FIG. 4 is a diagram illustrating an example of an attachment position of an antenna on a vehicle;

FIG. 5 is a diagram illustrating an example of a change in antenna performance that is caused in a case where an antenna is attached to a dashboard;

FIG. 6 is a flowchart illustrating an example of a flow of simulation processing of an integrated simulation system according to the embodiment;

FIG. 7 is a diagram illustrating an overall configuration example of an integrated simulation system according to a modification example;

FIG. 8 is a diagram illustrating an example of operation of each component of an integrated simulation system according to the modification example, and a flow of data; and

FIG. 9 is a flowchart illustrating an example of a flow of simulation processing of an integrated simulation system according to the modification example.

### DETAILED DESCRIPTION

Hereinafter, an embodiment of a simulation system according to the present disclosure will be described with reference to the drawings.

Overall Configuration of Integrated Simulation System

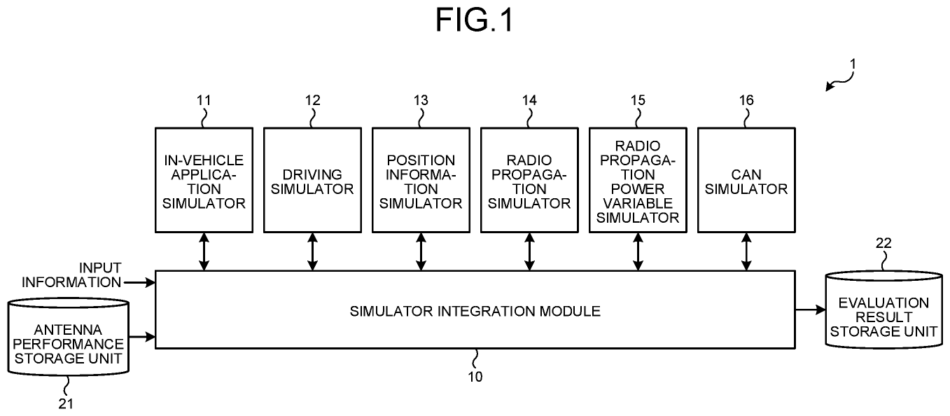

FIG. 1 is a diagram illustrating an overall configuration example of an integrated simulation system according to the embodiment. An overall configuration of an integrated simulation system 1 according to the present embodiment will be described with reference to FIG. 1.

The integrated simulation system 1 illustrated in FIG. 1 is a simulation system that performs ITS simulation being simulation processing for evaluating operation of an ITS application to be installed into an in-vehicle communication device such as a navigation device or an electronic control unit (ECU) device. Hereinafter, the ITS application will be sometimes simply referred to as an “application”. In order to perform evaluation and validation of operation of such an application, an actual vehicle test of causing several tens to several hundreds of vehicles to run under an actual traffic environment needs to be essentially performed. However, such an actual vehicle test has risks to test drivers and is very extensive. Therefore, it requires a lot of time and cost to obtain sufficient inclusiveness of evaluation items. In the final stage of development of the application, evaluation and validation by such an actual vehicle test are needed, but it is not practical to perform the actual vehicle test from the earlier stage of development. Moreover, as another aspect, the number of evaluation items for the technology of V2X has been increasing, and it is realistically difficult to evaluate all items in an actual vehicle test. Therefore, evaluation and validation of operation of the application need to be performed by simulation that uses the integrated simulation system 1 according to the present embodiment.

As illustrated in FIG. 1, the integrated simulation system 1 includes a simulator integration module 10, an in-vehicle application simulator 11, a driving simulator 12, a position information simulator 13, a radio propagation simulator 14, a radio propagation power variable simulator 15, a controller area network (CAN) simulator 16, an antenna performance storage unit 21, and an evaluation result storage unit 22. Note that, in a case where an optional one of the in-vehicle application simulator 11, the driving simulator 12, the position information simulator 13, the radio propagation simulator 14, the radio propagation power variable simulator 15, and the CAN simulator 16 is referred to, or in a case where these simulators are collectively referred to, the optional one and the simulators will each be simply referred to as “simulator(s)”.

The integrated simulation system 1 is applied a method of combining simulators in the simulator integration module 10 in such a manner that the simulators that perform simulation of a phenomenon consisting of a plurality of elements independently operate. By employing such a method, it becomes possible to appropriately select or replace each simulator in accordance with an evaluation purpose of operation of the application, and to execute more flexible simulation. In addition, instead of the method of combining the simulators in the simulator integration module 10 as in the integrated simulation system 1 illustrated in FIG. 1, a method in which simulators directly transmit and receive data may be employed.

The simulator integration module 10 is a module that controls operation of simulation to be executed by each simulator. For example, the simulator integration module 10 controls simulation to be executed by each simulator, by determining a start time and an end time of the simulation. Additionally, the simulator integration module 10 performs mediation of data transmission and reception between simulators.

Moreover, the simulator integration module 10 receives various types of input information and controls simulation on the basis of the input information. For example, the simulator integration module 10 receives, as input information, an instruction to produce an event of causing a vehicle to collide with another vehicle or a building structure, an instruction to produce a traffic jam event, etc., and outputs the event instruction to the driving simulator 12. In this case, the driving simulator 12 generates a driving scenario for producing the event, in accordance with the received event instruction. Note that the driving scenario will be described later.

The in-vehicle application simulator 11 is an application simulator for evaluating influence to be exerted on operation of a test vehicle, by simulating the ITS application. The driving simulator 12 is a simulator that generates a driving scenario and performs simulation in accordance with the driving scenario. The position information simulator 13 is a simulator that obtains a GNSS signal being position information (positioning information) to be acquired by a Global Navigation Satellite System (GNSS) device (positioning device) of each vehicle.

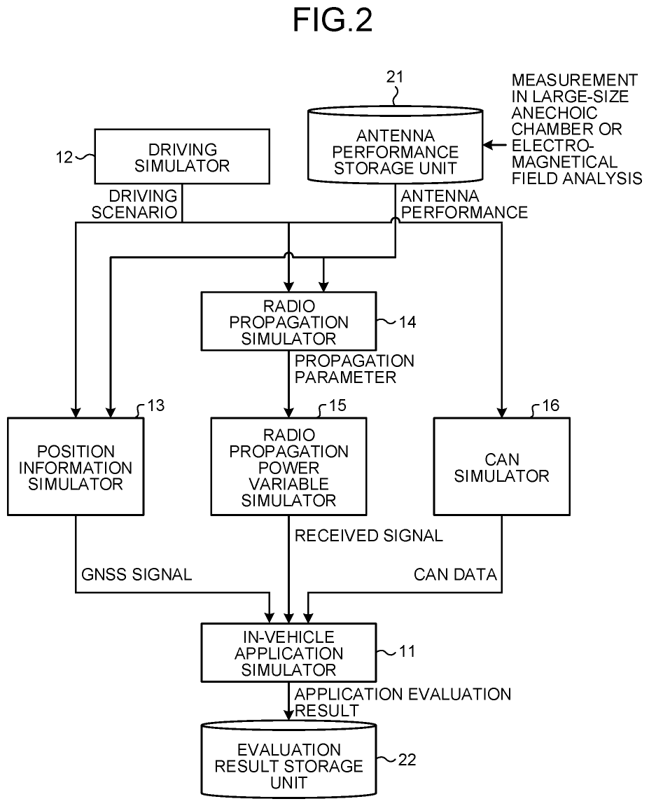

The radio propagation simulator 14 is a simulator that analyzes a radio propagation environment on the basis of antenna performance of an antenna installed in a test vehicle, and calculates a propagation parameter representing radio waves to be received by the antenna. The radio propagation power variable simulator 15 is a simulator that changes, on the assumption of an actual environment, a propagation parameter output from the radio propagation simulator 14 into a signal to be actually received by the antenna of the test vehicle. The CAN simulator 16 is an operation simulator that generates CAN data in the test vehicle from the driving scenario generated by the driving simulator 12. The detailed operation of each simulator will be described later with reference to FIG. 2 and subsequent diagrams.

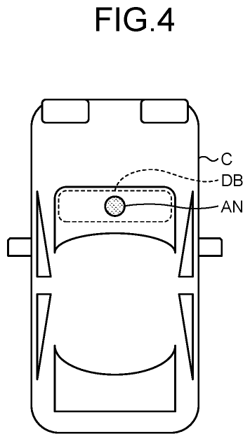

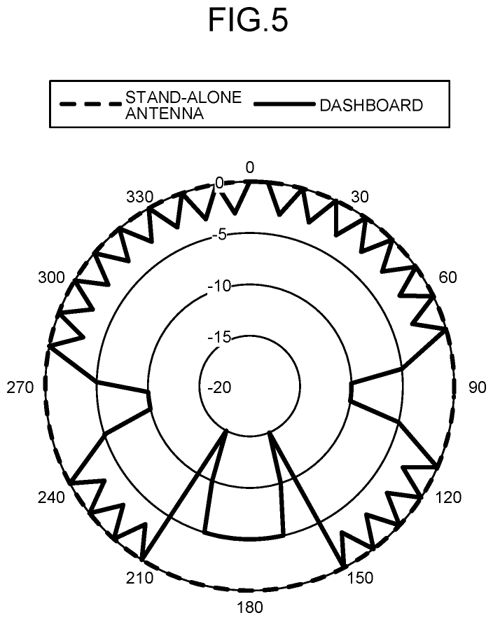

The antenna performance storage unit 21 is a storage device that stores information relative to antenna performance of an antenna installed in a vehicle. The antenna performance will be described later with reference to FIGS. 4 and 5. The evaluation result storage unit 22 is a storage device that stores an evaluation result of operation of the ITS application that is obtained by the in-vehicle application simulator 11.

Details of Operation of Each Component of Integrated Simulation System

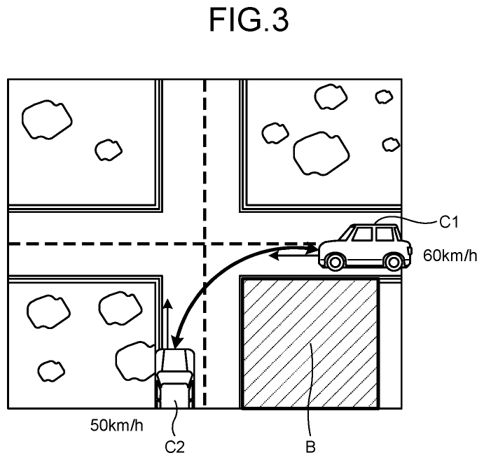

FIG. 2 is a diagram illustrating an example of operation of each component and a flow of data in an integrated simulation system according to the embodiment. FIG. 3 is a diagram describing an example of simulation of operation of a vehicle that is based on a driving scenario in an integrated simulation system according to the embodiment. FIG. 4 is a diagram illustrating an example of an attachment position of an antenna on a vehicle. FIG. 5 is a diagram illustrating an example of a change in antenna performance that is caused in a case where an antenna is attached to a dashboard. Operation of each component and a flow of data in the integrated simulation system 1 according to the present embodiment will be described with reference to FIGS. 2 to 5. Note that the illustration of the simulator integration module 10 is omitted in FIG. 2 to simply describe a flow of data, namely, to clarify data input-output between simulators and storage devices.

The driving simulator 12 performs simulation in accordance with a generated driving scenario. The driving scenario mentioned herein refers to information representing, for example, a road network, positions of roadside machines, positions of obstacles, buildings, etc., positions of a test vehicle and other vehicles, driving routes defining moving directions, behavior such as speed, etc. For example, in the example illustrated in FIG. 3, the driving scenario includes information relative to a vehicle C1 that is driving at 60 km/h toward a west side on a road extending east and west on the north side of a position of a building B, and information relative to a vehicle C2 that is driving at 50 km/h toward north on a road extending in a north-south direction on the west side of the position of the building B.

As described above, the driving simulator 12 can generate a driving scenario by using input information input by the simulator integration module 10. In a case where the input information includes, for example, an instruction to produce a traffic jam event, the driving simulator 12 can generate a driving scenario of gathering a large number of vehicles between predetermined two points to intentionally cause traffic jam between the two points.

As illustrated in FIGS. 1 and 2, the driving simulator 12 outputs, via the simulator integration module 10, the generated driving scenario to the position information simulator 13, the radio propagation simulator 14, and the CAN simulator 16.

The antenna performance storage unit 21 is a storage device that stores antenna performance of an antenna, namely, information relative to an antenna property. The antenna is used for transmission and reception of radio waves and is installed in each vehicle including a test vehicle. The antenna performance refers to properties regarding directivity of the antenna, and so forth. Specifically, the antenna performance represents the intensity (amplitude) of radio waves that can be transmitted and received in each direction around the antenna, phase properties of the radio waves, etc.

For example, FIG. 4 illustrates an example in which an antenna AN is installed in a dashboard DB in a vehicle interior of a vehicle C. The antenna performance, namely, the directivity of the antenna AN in this case has a property as illustrated in FIG. 5. In a case where the antenna AN is not installed in the vehicle C and is in a stand-alone state, and an obstacle or the like that disturbs radio wave transmission and reception via the antenna AN does not exist nearby, the antenna AN has an antenna property depicted with a dotted line in FIG. 5. In this property, radio wave transmission and reception performance of the stand-alone antenna AN is uniform in all directions, and performance of the stand-alone antenna AN has no directivity.

On the other hand, an antenna property in a case where the antenna AN is installed in the dashboard DB in the vehicle interior of the vehicle C, an antenna property can be represented by a solid line in FIG. 5. In this property, the antenna performance of the antenna AN varies in intensity of radio wave transmission and reception depending on the direction and has directivity. Specifically, the intensity of radio waves on the front of the vehicle C (that is, an upper in FIG. 5) is relatively good, whereas the intensity of radio waves on the lateral of the vehicle C (that is, left and right in FIG. 5) becomes smaller, and thereby the antenna property worsens. This is because a front door, a pillar, etc. of the vehicle C become barriers to the radio waves. Moreover, the intensity of radio waves on the rear of the vehicle C (that is, a lower in FIG. 5) becomes smaller, and thereby the antenna property worsens. This is because the rear of a roof, a hood, etc. of the vehicle C becomes barriers to the radio waves.

As described above, the antenna performance of the antenna AN, namely, the antenna property may vary with the attachment position of the antenna AN in the vehicle. In the integrated simulation system 1 according to the present embodiment, simulation of a transmission and reception operation is performed in consideration of actually-obtained antenna performance. As a method of deriving vehicle-installed antenna performance, there are a method of obtaining antenna performance by actual measurement, and a method of obtaining antenna performance by electromagnetic field analysis. In the case of the method of obtaining antenna performance by actual measurement, an antenna-installed vehicle is set in a large-size anechoic chamber being a shield space configured in such a manner that influence of electromagnetic waves from the outside is not received, electromagnetic waves do not leak to the outside, and moreover, electromagnetic waves are not reflected inside, for example, and vehicle-installed antenna performance such as amplitude, phase, and directivity that represent the intensity of radio waves to be transmitted and received by the antenna is measured and derived. On the other hand, in the case of the method of obtaining antenna performance by electromagnetic field analysis, by electromagnetic field analysis by numerical calculation that is based on Maxwell's equations for a model of an antenna-installed vehicle that has been created on simulation, vehicle-installed antenna performance such as amplitude, phase, and directivity that represent the intensity of radio waves to be transmitted and received by the antenna is analyzed and derived. In this manner, information relative to antenna performance obtained using either method of the method of obtaining antenna performance by actual measurement and the method of obtaining antenna performance by electromagnetic field analysis is stored in advance in the antenna performance storage unit 21.

Antennas for which the above-described antenna performance is to be derived include antennas to be used in a diversity method or a multiple input multiple output (MIMO) method, which is a method of receiving radio waves using two or more antennas. The diversity method is a method of achieving improvement in communication quality and reliability by preferentially using a signal of an antenna with a good radio wave condition from among the same radio signals received by a plurality of antennas, or performing noise removal processing, etc. by synthesizing received signals. On the other hand, the MIMO method is a method of achieving higher communication speed by realizing a pseudo wide band by simultaneously transmitting different radio signals from a plurality of antennas and synthesizing signals at the time of reception. Note that an antenna to be installed in a vehicle is not limited to a plurality of antennas to be used in the above-described diversity method or the MIMO method, and may be a single antenna.

The antenna performance storage unit 21 is implemented by a nonvolatile storage device such as a hard disk drive (HDD) or a solid state drive (SSD), for example.

The position information simulator 13 obtains a GNSS signal being position information to be acquired by a GNSS device of each vehicle, on the basis of an accurate position of each vehicle that is represented by the driving scenario generated by the driving simulator 12, and antenna performance of each vehicle that has been acquired from the antenna performance storage unit 21. The GNSS refers to a system that receives signals including time information, from a plurality of satellites, and measures a current position on the ground. As an example of the GNSS, for example, the global positioning system (GPS) developed in the United States is known. As illustrated in FIGS. 1 and 2, the position information simulator 13 outputs the generated GNSS signal to the in-vehicle application simulator 11 via the simulator integration module 10.

The radio propagation simulator 14 analyzes a radio propagation environment on the basis of the driving scenario generated by the driving simulator 12, and antenna performance of each vehicle that has been acquired from the antenna performance storage unit 21. The radio propagation simulator 14 then calculates a propagation parameter representing radio waves to be received by the antenna from another vehicle, a roadside unit, and other external devices. Specifically, the radio propagation simulator 14 calculates a propagation parameter representing radio waves to be received by the antenna, by adding antenna performance derived by actual measurement or analysis as described above, to nearby radio propagation performance. By using such antenna performance, a pseudo environment having reproducibility of a reality environment can be constructed, and ITS simulation reflecting real antenna performance can be performed. As illustrated in FIGS. 1 and 2, the radio propagation simulator 14 outputs the calculated propagation parameter to the radio propagation power variable simulator 15 via the simulator integration module 10.

The radio propagation power variable simulator 15 changes, on the assumption of an actual environment, the propagation parameter output from the radio propagation simulator 14 into a signal to be actually received by an antenna of a test vehicle. For example, the radio propagation power variable simulator 15 changes the propagation parameter into a received signal on the assumption of an actual environment such as influence of air or weather, influence of fading caused by reflected waves or the like, and a Doppler effect attributed to a driving speed. It is accordingly possible to simulate an actual environment such as an intersection at which Non-line-of sight communication is to be performed due to a building structure, and a driving environment in which radio waves are shielded by a plurality of vehicles. As illustrated in FIGS. 1 and 2, the radio propagation power variable simulator 15 outputs the changed received signal to the in-vehicle application simulator 11 via the simulator integration module 10.

The CAN simulator 16 generates CAN data being driving operation information representing a pedaling amount of an accelerator or a brake that is to be applied to a test vehicle being driving in accordance with the driving scenario generated by the driving simulator 12. As illustrated in FIGS. 1 and 2, the CAN simulator 16 outputs the generated CAN data to the in-vehicle application simulator 11 via the simulator integration module 10.

On the basis of the GNSS signal (position information) generated by the position information simulator 13, the received signal changed by the radio propagation power variable simulator 15, and the CAN data generated by the CAN simulator 16, the in-vehicle application simulator 11 simulates operation of the ITS application of the V2X that is installed in an in-vehicle communication device, and evaluates influence to be exerted on a test vehicle. Examples of specific operations of the ITS application include operation of warning a driver that there is a danger of collision and rear-end collision, or the like, by communicating position information of the own vehicle that has been acquired by a GNSS device such as a GPS device, to a nearby vehicle, operation of intervening in a driving operation to avoid the danger of collision, etc. Position information used in the in-vehicle application simulator 11 is not accurate position information obtained by the driving scenario generated by the driving simulator 12, but is the GNSS signal generated by the position information simulator 13. Therefore, the position information includes some level of positioning error. Accordingly, position information based on the GNSS signal including the positioning error is used, so that operation of a real ITS application can be simulated.

Note that, from the viewpoint of the purpose of constructing a pseudo environment having reproducibility of a reality environment, and performing ITS simulation reflecting real antenna performance, a GNSS signal including a positioning error needs not be always used. In this case, the in-vehicle application simulator 11 may use position information represented by the driving scenario generated by the driving simulator 12, instead of using the GNSS signal.

The in-vehicle application simulator 11 stores an evaluation result of operation of the ITS application into the evaluation result storage unit 22.

The evaluation result storage unit 22 is a storage device that stores an evaluation result of operation of the ITS application that is obtained by the in-vehicle application simulator 11. The evaluation result storage unit 22 is implemented by a nonvolatile storage device such as an HDD or an SSD, for example.

In addition, the simulator integration module 10, the in-vehicle application simulator 11, the driving simulator 12, the position information simulator 13, the radio propagation simulator 14, the radio propagation power variable simulator 15, and the CAN simulator 16, which have been described above, are implemented by a central processing unit (CPU) and a main storage device such as a random access memory (RAM) that are included in a normal information processing device. That is, computer programs for executing the simulator integration module 10 and the simulators are loaded onto the main storage device and executed by the CPU, whereby functions are implemented. Nevertheless, all the simulator integration module 10 and the simulators need not be implemented by the execution of computer programs. At least any of them may be implemented by hardware such as an application specific integrated circuit (ASIC) or a field-programmable gate array (FPGA).

In addition, the simulator integration module 10 and the simulators may be each implemented by a single information processing device, or may be implemented by distributed processing executed by a plurality of information processing devices.

Moreover, the antenna performance storage unit 21 and the evaluation result storage unit 22 described above may be storage devices such as an HDD or an SSD that are installed in an information processing device that implements each simulator, or may be storage devices installed in a database server different from the information processing device.

Flow of Simulation Processing

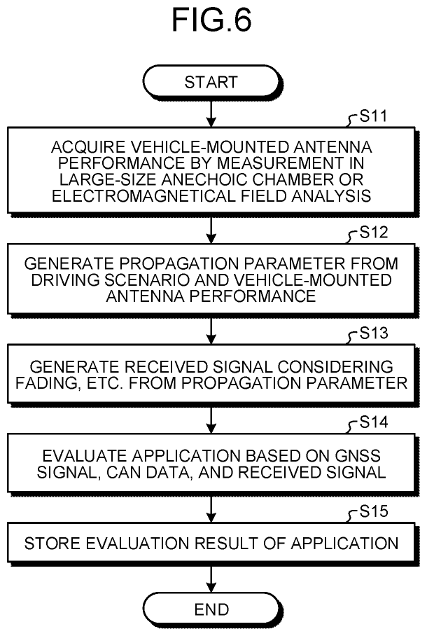

FIG. 6 is a flowchart illustrating an example of a flow of simulation processing of an integrated simulation system according to the embodiment. A flow of simulation processing of the integrated simulation system 1 according to the present embodiment will be described with reference to FIG. 6.

Step S11

The antenna performance of an antenna installed in a vehicle (test vehicle) is derived by the method of obtaining antenna performance by means of actual measurement or the method of obtaining antenna performance by means of electromagnetic field analysis. In the method of obtaining antenna performance by means of actual measurement, an antenna-installed vehicle is set in a large-size anechoic chamber, and vehicle-installed antenna performance such as intensity (amplitude), phase, and directivity of radio waves to be transmitted and received by the antenna is measured and derived. In the method of obtaining antenna performance by means of electromagnetic field analysis, by electromagnetic field analysis by numerical calculation that is based on Maxwell's equations, vehicle-installed antenna performance such as intensity (amplitude), phase, and directivity of radio waves to be transmitted and received by the antenna is analyzed and derived. The acquired antenna performance is stored into the antenna performance storage unit 21. Then, the processing proceeds to Step S12.

Step S12

In order to evaluate operation of the ITS application to be installed into an in-vehicle communication device, the simulator integration module 10 activates each simulator and starts ITS simulation. The driving simulator 12 generates a driving scenario on the basis of input information input by the simulator integration module 10, and starts simulation in accordance with the driving scenario. The driving simulator 12 outputs the generated driving scenario to the position information simulator 13, the radio propagation simulator 14, and the CAN simulator 16 via the simulator integration module 10.

The position information simulator 13 obtains a GNSS signal being position information to be acquired by a GNSS device of each vehicle, on the basis of an accurate position of each vehicle that is represented by the driving scenario generated by the driving simulator 12, and antenna performance of each vehicle that has been acquired from the antenna performance storage unit 21. Then, the position information simulator 13 outputs the generated GNSS signal to the in-vehicle application simulator 11 via the simulator integration module 10. The CAN simulator 16 generates CAN data being driving operation information representing a pedaling amount of an accelerator or a brake that is to be generated while a test vehicle is driving in accordance with the driving scenario generated by the driving simulator 12. Then, the CAN simulator 16 outputs the generated CAN data to the in-vehicle application simulator 11 via the simulator integration module 10.

The radio propagation simulator 14 analyzes a radio propagation environment on the basis of the driving scenario generated by the driving simulator 12 and antenna performance of each vehicle that has been acquired from the antenna performance storage unit 21. Then, the radio propagation simulator 14 calculates a propagation parameter representing radio waves to be received by the antenna. Specifically, the radio propagation simulator 14 calculates a propagation parameter representing radio waves to be received by the antenna, by adding antenna performance derived by actual measurement or analysis described above, to nearby radio propagation performance. Then, the processing proceeds to Step S13.

Step S13

The radio propagation power variable simulator 15 changes, on the assumption of an actual environment, the propagation parameter output from the radio propagation simulator 14 into a signal to be actually received by an antenna of a test vehicle, in consideration of the influence of fading, etc. The radio propagation power variable simulator 15 outputs the changed received signal to the in-vehicle application simulator 11 via the simulator integration module 10. Then, the processing proceeds to Step S14.

Step S14

On the basis of the GNSS signal (position information) generated by the position information simulator 13, the received signal changed by the radio propagation power variable simulator 15, and the CAN data generated by the CAN simulator 16, the in-vehicle application simulator 11 simulates operation of the ITS application of the V2X that is installed in an in-vehicle communication device, and evaluates influence to be exerted on a test vehicle. Then, the processing proceeds to Step S15.

Step S15

The in-vehicle application simulator 11 stores the obtained evaluation result of operation of the ITS application into the evaluation result storage unit 22.

Subsequently, the integrated simulation system 1 continues the simulation processing while repeating Steps S12 to S15.

As described above, in the integrated simulation system 1 according to the present embodiment, when a test vehicle receives radio waves from another vehicle, a roadside unit, and other external devices via an antenna in accordance with a driving scenario generated by the driving simulator 12, the radio propagation simulator 14 calculates a propagation parameter representing radio waves to be received by the antenna, on the basis of vehicle-installed antenna performance obtained by actual measurement or analysis. By using actual antenna performance in this manner, a pseudo environment having reproducibility of a reality environment can be constructed, and ITS simulation reflecting real antenna performance can be performed.

### Modification Example

An integrated simulation system according to the modification example will be mainly described in regard to a difference from the integrated simulation system 1 according to the above-described embodiment. In the above-described embodiment, the description has been given of operation of deriving antenna performance of an antenna installed in a vehicle, by actual measurement or analysis, and using the antenna performance in simulation. As described above, antennas to be installed in such a vehicle are antennas to be used in the diversity method or the MIMO method, which is a method of receiving radio waves using two or more antennas. In the modification example, the description will be given of operation of performing ITS simulation after converting antenna performance obtained by actual measurement or analysis for two or more antennas, into antenna performance of a single antenna, in a case where such two or more antennas to be used in the diversity method or the MIMO method are included.

Overall Configuration of Integrated Simulation System and Operation of Each Component

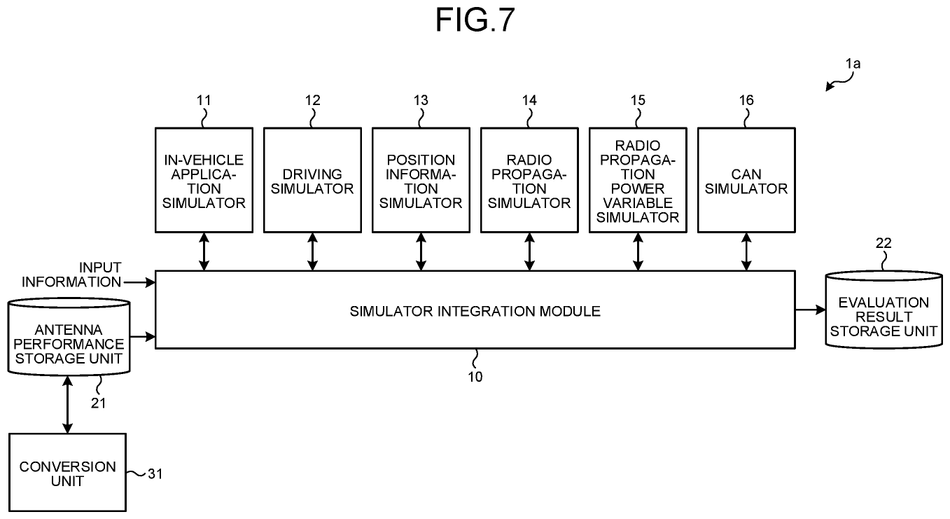

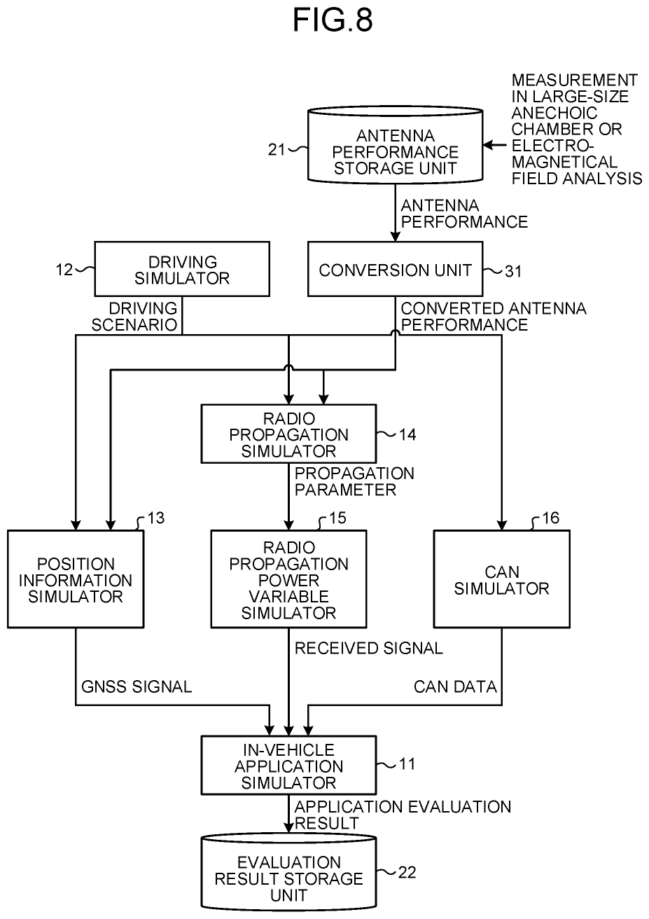

FIG. 7 is a diagram illustrating an overall configuration example of an integrated simulation system according to a modification example. FIG. 8 is a diagram illustrating an example of operation of each component of an integrated simulation system according to the modification example, and a flow of data. An overall configuration of an integrated simulation system 1a according to this modification example, and operation of each component will be described with reference to FIGS. 7 and 8.

As illustrated in FIG. 7, the integrated simulation system 1a includes a simulator integration module 10, an in-vehicle application simulator 11, a driving simulator 12, a position information simulator 13, a radio propagation simulator 14, a radio propagation power variable simulator 15, a CAN simulator 16, an antenna performance storage unit 21, an evaluation result storage unit 22, and a conversion unit 31 (an example of a converter). In addition, functions of the simulator integration module 10, the in-vehicle application simulator 11, the driving simulator 12, the position information simulator 13, the radio propagation simulator 14, the radio propagation power variable simulator 15, the CAN simulator 16, and the evaluation result storage unit 22, which have been described above, are similar to the functions described in the above-described embodiment with reference to FIGS. 1 and 2.

The antenna performance storage unit 21 is a storage device that stores antenna performance of an antenna used for transmission and reception of radio waves that is installed in a vehicle including a test vehicle, that is to say, information relative to an antenna property. As described above, antenna performance is derived by the method of obtaining antenna performance by actual measurement or the method of obtaining antenna performance by electromagnetic field analysis. At this time, as described above, antennas to be installed in a vehicle are antennas to be used in the diversity method or the MIMO method, which is a method of receiving radio waves using two or more antennas. In this case, antenna performance is obtained for each of a plurality of antennas, but if processing is performed by the radio propagation simulator 14 in this case using antenna performance of each antenna as-is, a processing amount becomes enormous, which is problematic. For example, in a case where simulation of communication between vehicles each including four antennas is performed in the radio propagation simulator 14, as compared with a processing amount required in a case where communication is performed between vehicles each including a single antenna, a required processing amount becomes sixteen (4×4=16) times. In view of the foregoing, in this modification example, antenna performance obtained by actual measurement or analysis for two or more antennas is converted into antenna performance of a single antenna. The conversion operation will be described as operation of the conversion unit 31 to be described below.

The conversion unit 31 reads out antenna performance obtained by actual measurement or analysis for a plurality of antennas that is stored in the antenna performance storage unit 21. The conversion unit 31 then converts the antenna performance into antenna performance that is obtained on the assumption that the plurality of antennas is a single antenna. Specifically, the conversion unit 31 calculates a diversity gain, MIMO performance, or the like that represent an effect obtained by using of a plurality of antennas, by numerical analysis from antenna performance obtained by actual measurement or analysis for a plurality of antennas that has been read from the antenna performance storage unit 21. Next, by obtaining a diversity gain, etc. that represent an effect of a single antenna on the basis of the calculated diversity gain or MIMO performance for a plurality of antennas, the conversion unit 31 converts the antenna performance into antenna performance that is obtained on the assumption that the plurality of antennas is a single antenna. In this case, the conversion unit 31 may correct the calculated diversity gain on the basis of a noise power ratio. Then, the conversion unit 31 stores the converted antenna performance, which is obtained on the assumption that the plurality of antennas is a single antenna, into the antenna performance storage unit 21.

Note that the conversion unit 31 is implemented by a CPU and a main storage device such as a RAM, which are provided in an information processing device. A computer program for executing a function of the conversion unit 31 is loaded onto the main storage device and executed by the CPU, whereby the function is implemented. Nevertheless, the conversion unit 31 needs not be implemented by the execution of the computer program, and may be implemented by hardware such as an ASIC or an FPGA.

Flow of Simulation Processing

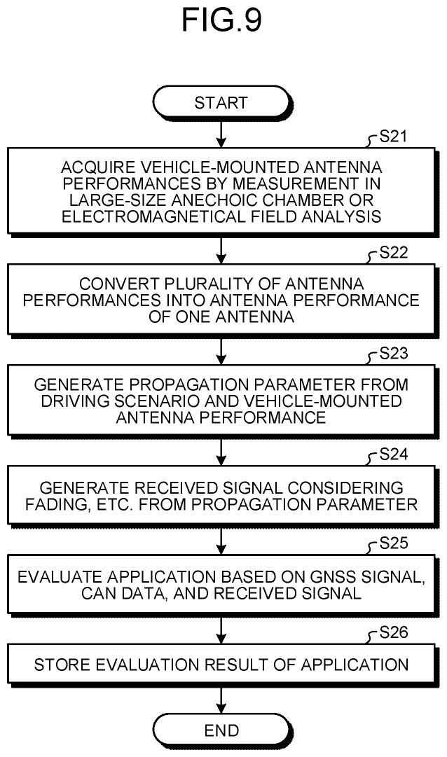

FIG. 9 is a flowchart illustrating an example of a flow of simulation processing of an integrated simulation system according to the modification example. A flow of simulation processing of the integrated simulation system 1a according to this modification example will be described with reference to FIG. 9.

Step S21

The antenna performances of a plurality of antennas installed in a vehicle (test vehicle) are derived by the method of obtaining antenna performance by actual measurement or the method of obtaining antenna performance by electromagnetic field analysis. The acquired antenna performances of the plurality of antennas are stored into the antenna performance storage unit 21. Then, the processing proceeds to Step S22.

Step S22

The conversion unit 31 reads out antenna performance obtained by actual measurement or analysis for a plurality of antennas that is stored in the antenna performance storage unit 21. The conversion unit 31 then converts the antenna performance into antenna performance that is obtained on the assumption that the plurality of antennas is a single antenna. Specifically, the conversion unit 31 calculates a diversity gain, MIMO performance, etc. that represent an effect obtained by using of a plurality of antennas, by numerical analysis from antenna performance obtained by actual measurement or analysis for a plurality of antennas that has been read from the antenna performance storage unit 21. Next, by obtaining a diversity gain, etc. that represent an effect of a single antenna on the basis of the calculated diversity gain or MIMO performance for a plurality of antennas, the conversion unit 31 converts the antenna performance into antenna performance obtained on the assumption that the plurality of antennas is a single antenna. The conversion unit 31 stores the converted antenna performance obtained on the assumption that the plurality of antennas is a single antenna, into the antenna performance storage unit 21. Then, the processing proceeds to Step S23.

Step S23

In order to evaluate operation of the ITS application to be installed into an in-vehicle communication device, the simulator integration module 10 activates each simulator and starts ITS simulation. The driving simulator 12 generates a driving scenario on the basis of input information input by the simulator integration module 10 and starts simulation in accordance with the driving scenario. The driving simulator 12 outputs the generated driving scenario to the position information simulator 13, the radio propagation simulator 14, and the CAN simulator 16 via the simulator integration module 10.

The position information simulator 13 obtains a GNSS signal being position information to be acquired by a GNSS device of each vehicle, on the basis of an accurate position of each vehicle that is represented by the driving scenario generated by the driving simulator 12, and antenna performance of each vehicle that has been acquired from the antenna performance storage unit 21. Then, the position information simulator 13 outputs the generated GNSS signal to the in-vehicle application simulator 11 via the simulator integration module 10. The CAN simulator 16 generates CAN data being driving operation information representing a pedaling amount, etc. of an accelerator or a brake that is to be generated while a test vehicle is driving in accordance with the driving scenario generated by the driving simulator 12. Then, the CAN simulator 16 outputs the generated CAN data to the in-vehicle application simulator 11 via the simulator integration module 10.

The radio propagation simulator 14 analyzes a radio propagation environment on the basis of: the driving scenario generated by the driving simulator 12, and antenna performance of each vehicle obtained on the assumption that the plurality of antennas is a single antenna, which has been acquired from the antenna performance storage unit 21. The radio propagation simulator 14 then calculates a propagation parameter representing radio waves to be received by the antenna. Specifically, the radio propagation simulator 14 calculates a propagation parameter representing radio waves to be received by the antenna, by adding antenna performance derived by actual measurement or analysis as described above, to nearby radio propagation performance. Then, the processing proceeds to Step S24.

Steps S24 to S26

The processing in Steps S24 to S26 is similar to the above-described processing in Step S13 to S15 illustrated in FIG. 6.

As described above, in the integrated simulation system 1a according to this modification example, antenna performance obtained by actual measurement or analysis for two or more antennas is converted by the conversion unit 31 into antenna performance of a single antenna, and ITS simulation is performed. With this configuration, in the simulation executed by the radio propagation simulator 14, by using antenna performance obtained on the assumption that the plurality of antennas is a single antenna, as compared with a case where antenna performances of a plurality of antennas are used as-is, a processing amount can be reduced, and the generation of delay or the like of processing of the entire ITS simulation can be prevented. In addition, needless to say, an effect similar to the effect of the integrated simulation system 1 according to the above-described embodiment is caused also in the integrated simulation system 1a according to this modification example.

In addition, computer programs to be executed in the integrated simulation systems 1 and 1a according to the above-described embodiment and the modification example may be provided by being recorded onto a computer-readable recording medium such as a compact disk read only memory (CD-ROM), a flexible disk (FD), a CD recordable (CD-R), or a digital versatile disk (DVD) in an installable format or executable format file. The computer programs to be executed in the integrated simulation systems 1 and 1a according to the above-described embodiment and the modification example may be stored onto a computer connected to a network such as the internet, and provided by being downloaded via the network. The computer programs to be executed in the integrated simulation systems 1 and 1a according to the above-described embodiment and the modification example may be provided or distributed via a network such as the internet. The computer programs to be executed in the integrated simulation systems 1 and 1a according to the above-described embodiment and the modification example may be provided by being preinstalled into a ROM or the like.

Moreover, the computer programs for executing processing in the integrated simulation systems 1 and 1a according to the above-described embodiment and the modification example have a module configuration including the above-described components. As actual hardware, for example, a CPU serving as an arithmetic device reads computer programs from a read only memory (ROM) or an auxiliary storage device such as an HDD or an SSD, and executes the computer programs. The plurality of above-described components is accordingly loaded onto the RAM serving as a main storage device, and the plurality of above-described components is generated on the RAM.

While certain embodiments have been described, these embodiments have been presented by way of example only, and are not intended to limit the scope of the inventions. Indeed, the novel methods and systems described herein may be embodied in a variety of other forms; moreover, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A simulation system comprising:
a driving simulator configured to generate a driving scenario representing at least behavior of a vehicle;
a radio propagation simulator configured to calculate a propagation parameter representing a radio wave to be received by one or more antennas installed in the vehicle, the propagation parameter being calculated on the basis of antenna performance of the one or more antennas and a position of the vehicle, the position of the vehicle being indicated by the driving scenario generated by the driving simulator; and
an application simulator configured to simulate operation of an application serving to control operation of the vehicle, the operation of the application being simulated by using at least information based on the propagation parameter.

2. The simulation system according to claim 1, wherein the antenna performance is derived by measuring a radio wave to be received by each of the one or more antennas installed in the vehicle, the radio wave being measured in an anechoic chamber in which the vehicle is set.

3. The simulation system according to claim 1, wherein the antenna performance is derived by electromagnetic field analysis for a model of the vehicle on which the one or more antennas are installed.

4. The simulation system according to claim 1, wherein
the one or more antennas of the vehicle are constituted by a plurality of antennas,
the simulation system further comprises a converter configured to convert the antenna performance obtained from the plurality of antennas into antenna performance obtained on an assumption that the plurality of antennas is a single antenna, and
the radio propagation simulator is configured to perform the calculation of the propagation parameter on the basis of the antenna performance converted by the converter.

5. The simulation system according to claim 1, further comprising a variable simulator configured to change the propagation parameter calculated by the radio propagation simulator into a received signal to be actually received by each of the one or more antennas on the assumption of an actual environment.

6. The simulation system according to claim 1, further comprising a position information simulator configured to obtain position information to be acquired by a positioning device of the vehicle, the position information being obtained on the basis of a position of the vehicle indicated by the driving scenario and the antenna performance,
wherein the application simulator is configured to perform the simulation of the operation of the application by further using the position information obtained by the position information simulator.

7. The simulation system according to claim 1, wherein the application simulator is configured to perform the simulation of the operation of the application by further using position information indicated by the driving scenario.

8. The simulation system according to claim 1, further comprising an operation simulator configured to generate driving operation information representing a driving operation to be applied to the vehicle being driving in accordance with the driving scenario,
wherein the application simulator is configured to perform the simulation of the operation of the application by further using the driving operation information generated by the operation simulator.

9. The simulation system according to claim 1, wherein the antenna performance represents directivity of the one or more antennas.

10. A simulation method comprising:
generating a driving scenario representing at least behavior of a vehicle;
calculating a propagation parameter representing a radio wave to be received by one or more antennas installed in the vehicle, the propagation parameter being calculated on the basis of antenna performance of the one or more antennas and a position of the vehicle, the position of the vehicle being indicated by the driving scenario; and
simulating operation of an application serving to control operation of the vehicle, the operation of the application being simulated by using at least information based on the propagation parameter.

11. A non-transitory computer-readable recording medium on which programmed instructions are recorded, the instructions causing a computer to execute processing, the processing executed by the computer comprising:
generating a driving scenario representing at least behavior of a vehicle;
calculating a propagation parameter representing a radio wave to be received by one or more antennas installed in the vehicle, the propagation parameter being calculated on the basis of antenna performance of the one or more antennas and a position of the vehicle, the position of the vehicle being indicated by the driving scenario; and
simulating operation of an application serving to control operation of the vehicle, the operation of the application being simulated by using at least information based on the propagation parameter.
